(19) United States
(12) Patent Application Publication
(10) Pub. No.: US 2011/0127533 A1
(43) Pub. Date: Jun. 2, 2011

(54) ORGANIC LIGHT-EMITTING DISPLAY DEVICE AND METHOD OF MANUFACTURING THE SAME

(75) Inventors: Hyun-Joong Chung, Yongin-City (KR); Jin-Seong Park, Yongin-City (KR); Yeon-Gon Mo, Yongin-City (KR); Jong-Han Jeong, Yongin-City (KR)

(73) Assignee: SAMSUNG MOBILE DISPLAY CO., LTD., Yongin-City (KR)

(21) Appl. No.: 12/955,753

(22) Filed: Nov. 29, 2010

(30) Foreign Application Priority Data
Nov. 30, 2009 (KR) 10-2009-0117074

(51) Int. Cl. H01L 51/50; H01L 51/40

(52) U.S. Cl. 257/59; 438/23; 257/E51.018; 257/E51.005

(57) ABSTRACT

An organic light-emitting display device which may be configured to prevent oxygen or water from penetrating from the outside and which may be more easily mass produced is disclosed. A method of manufacturing an organic light-emitting display device is also disclosed. The organic light-emitting display device may include, for example, a thin-film transistor (TFT) with a gate electrode, an active layer electrically insulated from the gate electrode, source and drain electrodes electrically insulated from the gate electrode and contacting the active layer, an organic light-emitting diode electrically connected to the TFT and an insulating layer interposed between the TFT and the organic light-emitting diode. The insulating layer may include, for example, a first insulating layer covering the TFT, a second insulating layer formed of metal oxide and formed on the first insulating layer and a third insulating layer formed of metal oxide or metal nitride and formed on the second insulating layer.

### CROSS-REFERENCE TO RELATED APPLICATIONS

This application claims the benefit of Korean Patent Application No. 10-2009-0117074, filed on Nov. 30, 2009, in the Korean Intellectual Property Office, the disclosure of which is incorporated herein in its entirety by reference.

### BACKGROUND

1. Field of the Invention

The present invention relates to an organic light-emitting display device including a thin-film transistor (TFT) and a method of manufacturing the device.

2. Description of the Related Art

Active matrix type organic light-emitting display devices include a thin-film transistor (TFT) and an organic light-emitting diode connected to the TFT in each pixel. An active layer of the TFT is formed of amorphous silicon or polysilicon. Recently, there have been attempts to form the active layer of an oxide semiconductor. The characteristics of the oxide semiconductor, however, such as a threshold voltage, an S-factor, or the like, may be easily changed due to oxygen or water that penetrates from the outside. The change of the threshold voltage due to the oxygen or water is further affected by a direct current (DC) bias of a gate electrode while driving the TFT, and thus DC stability has become the biggest problem in using an oxide semiconductor.

An AlOₓ layer or a TiN layer may be used in the oxide semiconductor in order to enhance a barrier characteristic of the oxide semiconductor against water or oxygen. Since the AlOₓ layer or the TiN layer is manufactured by reactive sputtering or atomic layer deposition (ALD), it is difficult to use the AlOₓ layer or the TiN layer in a large area substrate. Further, it is more difficult to mass produce the organic light-emitting display device.

### SUMMARY OF CERTAIN INVENTIVE ASPECTS

In one aspect, an organic light-emitting display device may include, for example, a thin-film transistor (TFT) capable of preventing oxygen or water from penetrating from the outside, and a method of manufacturing the device.

In another aspect, an organic light-emitting display device is disclosed, which can be easily used in a large area display device. In some embodiments, the device may be easily mass produced.

In another aspect, a method of manufacturing an organic light-emitting display device is provided.

In another aspect, an organic light-emitting display device includes, for example, a thin-film transistor (TFT) comprising a gate electrode, an active layer insulated from the gate electrode, and source and drain electrodes insulated from the gate electrode and contacting the active layer; an organic light-emitting diode electrically connected to the TFT and an insulating layer interposed between the TFT and the organic light-emitting diode.

In some embodiments, the insulating layer includes, for example, a first insulating layer covering the TFT, a second insulating layer formed of a metal oxide and formed on the first insulating layer, and a third insulating layer formed of a metal and formed on the second insulating layer. In some embodiments, the second insulating layer has a gradient of metal content with respect to its thickness. In some embodiments, the metal content decreases toward the first insulating layer. In some embodiments, the metal is formed of a metal oxide, a metal nitride, aluminum or titanium. In some embodiments, the insulating layer further comprises a fourth insulating layer formed on the third insulating layer. In some embodiments, the third insulating layer is formed of aluminum oxide, aluminum nitride, titanium oxide or titanium nitride. In some embodiments, the insulating layer further comprises a metal layer between the second insulating layer and the third insulating layer. In some embodiments, the metal layer is formed of aluminum, titanium or an alloy thereof. In some embodiments, the active layer is formed of an oxide semiconductor. In some embodiments, the first insulating layer is formed of silicon oxide.

In another aspect, a method of manufacturing an organic light-emitting display device, the method includes, for example, forming a thin-film transistor (TFT) on a substrate, wherein the TFT comprises a gate electrode, an active layer insulated from the gate electrode, and source and drain electrodes insulated from the gate electrode and contacting the active layer; forming an insulating layer covering the TFT and forming an organic light-emitting diode on the insulating layer, wherein the organic light-emitting diode is electrically connected to at least one of the source electrode and the drain electrode.

In some embodiments, the forming of the insulating layer includes, for example, forming a first insulating layer covering the TFT; forming a metal layer on the first insulating layer; forming a part of the metal layer as a third insulating layer by oxidizing or nitrifying a surface of the metal layer opposite to the first insulating layer and forming a second insulating layer formed of metal oxide in a portion where the first insulating layer and the metal layer contact each other. In some embodiments, the forming of the second insulating layer includes, for example, performing a thermal treatment on the metal layer. In some embodiments, the second insulating layer has a gradient of metal content with respect to its thickness. In some embodiments, the metal content decreases toward the first insulating layer. In some embodiments, the metal is formed of aluminum, titanium or an alloy thereof. In some embodiments, the method further includes, for example, forming a fourth insulating layer on the third insulating layer. In some embodiments, the third insulating layer is formed of aluminum oxide, aluminum nitride, titanium oxide or titanium nitride. In some embodiments, the method further includes, for example, forming a metal layer between the second insulating layer and the third insulating layer. In some embodiments, the metal layer is formed of aluminum, titanium or an alloy thereof. In some embodiments, the active layer is formed of an oxide semiconductor. In some embodiments, the first insulating layer is formed of silicon oxide.

In some embodiments of the present disclosure, the insulating layer may be configured to further increase a barrier effect with respect to an active layer. Thus, in some embodiments, the insulating layer is configured to protect a TFT, including, for example, the active layer with an oxide semiconductor against oxygen or water. In some embodiments, a layer having an excellent barrier characteristic, such as AlOₓ or TiN, is not manufactured by reactive sputtering or atomic layer deposition (ALD), and thus may be easily used in a large-sized substrate, thereby the devices produced by the methods disclosed may be more easily mass produced.

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus according to some of the described embodiments can have several aspects, no single one of which necessarily is solely responsible for the desirable attributes of the apparatus. After considering this discussion, and particularly after reading the section entitled “Detailed Description of Certain Inventive Embodiments” one will understand how illustrated features serve to explain certain principles of the present disclosure.

FIG. 1 is a schematic cross-sectional view illustrating an organic light-emitting display device.

FIG. 2 is a cross-sectional view of region A of FIG. 1, according to an embodiment of the present disclosure.

FIG. 3 is a cross-sectional view of region A of FIG. 1, according to another embodiment of the present disclosure.

FIG. 4 is a cross-sectional view of region A of FIG. 1, according to another embodiment of the present disclosure.

FIG. 5 is a cross-sectional view of region A of FIG. 1, according to another embodiment of the present disclosure.

FIGS. 6A through 6E are cross-sectional views sequentially illustrating a method of manufacturing the organic light-emitting display device of FIG. 2.

FIGS. 7A through 7E are cross-sectional views sequentially illustrating a method of manufacturing the organic light-emitting display device of FIG. 4.

### DETAILED DESCRIPTION OF CERTAIN INVENTIVE EMBODIMENTS

In the following detailed description, only certain exemplary embodiments have been shown and described, simply by way of illustration. As those skilled in the art would realize, the described embodiments may be modified in various different ways, all without departing from the spirit or scope of the present disclosure. Further, in several exemplary embodiments, constituent elements having the same construction are assigned the same reference numerals and are representatively described in connection with a first exemplary embodiment. In the remaining exemplary embodiments, constituent elements different from those of the first exemplary embodiment are described. To clarify the description of the exemplary embodiments, the same reference numbers will be used throughout the drawings to refer to the same or like parts. Further, the size and thickness of each of the elements shown in the drawings are arbitrarily shown for better understanding and ease of description, and the embodiments are not limited thereto.

In addition, in the drawings, the thickness of layers, films, panels, regions, etc., are exaggerated for clarity. The thickness of the layers, films, panels, regions, etc., is enlarged in the drawings for better understanding and ease of description. Accordingly, the drawings and description are to be regarded as illustrative in nature and not restrictive. It will be understood that when an element such as a layer, film, region, or substrate is referred to as being “on” another element, it can be directly on the other element or intervening elements may also be interposed therebetween. Also, when an element is referred to as being “connected to” another element, it can be directly connected to the other element or be indirectly connected to the other element with one or more intervening elements interposed therebetween.

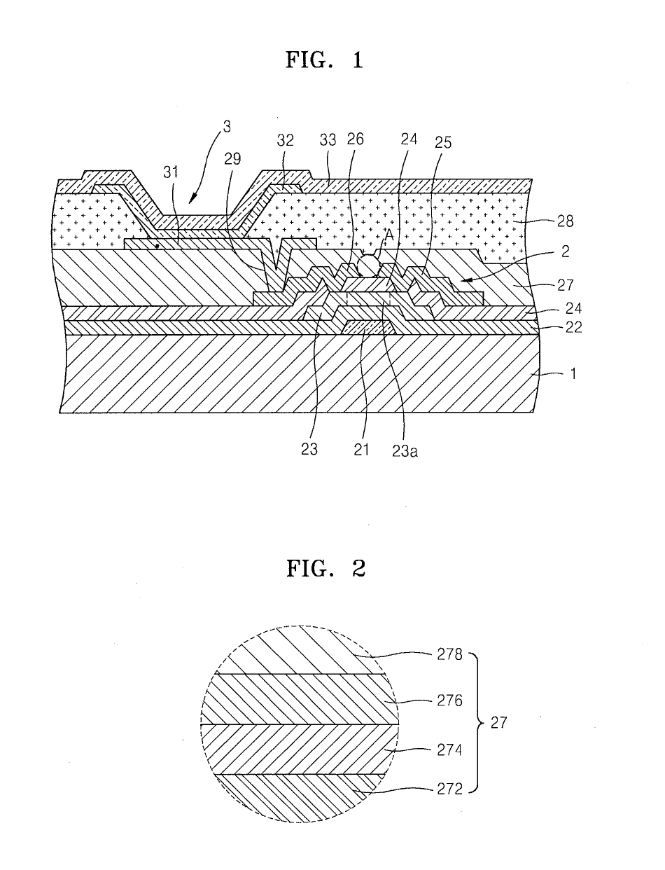

FIG. 1 is a schematic cross-sectional view illustrating an organic light-emitting display device according to an embodiment of the present disclosure. Referring to FIG. 1, a thin-film transistor (TFT) 2 and an organic light-emitting diode (OLED) 3 are formed on a substrate 1. FIG. 1 illustrates a part of a pixel of the organic light-emitting display device. However, it will be understood by those of skill in the art informed by the present disclosure that the organic light-emitting display device may include a plurality of pixels.

The TFT 2 includes a gate electrode 21 formed on the substrate 1, a gate insulating layer 22 covering the gate electrode 21, an active layer 23 formed on the gate insulating layer 22, an etch stopper layer 24 formed on the gate insulating layer 22 so as to cover the active layer 23, and a source electrode 25 and a drain electrode 26 that are formed on the etch stopper layer 24 and contact the active layer 23. In FIG. 1, the TFT 2 has a bottom gate structure; however embodiments of the present disclosure are not limited thereto, and thus the TFT 2 may have a top gate structure.

In some embodiments, a buffer layer (not shown) may be formed of an inorganic material, such as silicon oxide, on the substrate 1. The gate electrode 21 formed on the substrate 1 may be formed of a conductive metal in a single-layer structure or a multi-layer structure. The gate electrode 21 may include molybdenum. The gate insulating layer 22 may be formed, for example, of silicon oxide, tantalum oxide or aluminum oxide. The patterned active layer 23 formed on the gate insulating layer 22 may be formed of an oxide semiconductor, for example, a G-I-Z-O layer [a(In₂O₃)a(Ga₂O₃)b(ZnO)c layer] (a, b, and, c are real numbers which satisfy the conditions of a≧0, b≧0, and c>0).

The etch stopper layer 24 covers the active layer 23. In particular, the etch stopper layer 24 is configured to protect a channel 23a of the active layer 23. As illustrated in FIG. 1, the etch stopper layer 24 may cover the entire active layer 23, except for regions where the source and drain electrodes 25 and 26 contact the active layer 23, but the present disclosure is not limited thereto. Although not shown in FIG. 1, the etch stopper layer 24 may be formed only on the channel 23a.

The source electrode 25 and the drain electrode 26 are formed on the etch stopper layer 24 so as to contact the active layer 23. An insulating layer 27 may be formed to cover the source electrode 25 and the drain electrode 26 on the etch stopper layer 24. A first electrode 31 of the OLED 3 contacting the drain electrode 26 may be formed on the insulating layer 27. The drain electrode 26 and the first electrode 31 may contact each other by forming a via-hole 29 in the insulating layer 27.

In some embodiments, a pixel-defining layer 28 exposing a part of the first electrode 31 is formed on the insulating layer 27. An organic layer 32 and a second electrode 33 are formed on the first electrode 31 exposed by the pixel-defining layer 28. The first electrode 31 may be patterned for each pixel. When the OLED has a top emission type structure, the first electrode 31 may be a reflective electrode. The reflective electrode may be formed of an alloy including, for example, Al, Ag or the like.

When the first electrode 31 is an anode, the first electrode 31 may include a layer formed of a metal oxide, for example, ITO, IZO, In₂O₃ or ZnO, with a high work function (absolute value). When the first electrode 31 is a cathode, the first electrode 31 may include a high conductive metal, for example, Ag, Mg, Al, Pt, Pd, Au, Ni, Nd, Ir, Cr, Li or Ca, with a low work function (absolute value). Accordingly, in this case, the aforementioned reflective layer may not be necessary.

The second electrode 33 may be a light transmissive electrode. Thus, the second electrode 33 may include, for example, a semi-transmissive reflective layer formed as a thin film. The thin film may be formed of Ag, Mg, Al, Pt, Pd, Au, Ni, Nd, Ir, Cr, Li, Ca and the like, or it may include a light transmissive metal oxide formed of ITO, IZO, ZnO and the like. When the first electrode 31 is an anode, the second electrode 33 is a cathode and when the first electrode 31 is a cathode, the second electrode 33 is an anode.

The organic layer 32 interposed between the first electrode 31 and the second electrode 33 may include, for example, a hole injection layer (HIL), a hole transport layer (HTL), an emission layer (EML), an electron injection layer (EIL), an electron transport layer (ETL), etc., some or all of which may be included in a stack structure. The EML, for example, may be omitted.

Although not shown in FIG. 1, in some embodiments, a passivation layer may be formed on the second electrode 33 and the organic light-emitting display may be sealed using glass.

The insulating layer 27 may be formed as illustrated in FIG. 2. FIG. 2 illustrates region A of FIG. 1 according to an embodiment of the present disclosure. Referring to FIG. 2, the insulating layer 27 may include, for example, a first insulating layer 272 contacting the etch stopper layer 24, a second insulating layer 274 formed on the first insulating layer 272, a third insulating layer 276 formed on the second insulating layer 274 and a fourth insulating layer 278 formed on the third insulating layer 276.

The first insulating layer 272 may include, for example, an oxide layer formed of SiOₓ formed by plasma-enhanced chemical vapor deposition (PECVD) or sputtering. In some embodiments, the oxide layer is configured to protect the active layer 23 against pollution due to the forming of the metal layer and is configured to facilitate diffusion of a metal by a thermal treatment in a later process.

In some embodiments, the second insulating layer 274 may include a metal oxide and may have a gradient of metal content depending on a thickness of the second insulating layer 274. In this instance, the concentration of the metal content of the second insulating layer 274 may decrease toward the first insulating layer 272. Accordingly, the metal content of a portion where the second insulating layer 274 and the third insulating layer 276 contact each other is highest, and the metal content of a portion where the second insulating layer 274 and the first insulating layer 272 contact each other is lowest. The metal may be aluminum or titanium. Thus, the second insulating layer 274 may include silicon oxide and aluminum or titanium, wherein the aluminum or titanium may be diffused into the silicon oxide so that the content of aluminum or titanium has a concentration gradient depending on a thickness of the second insulating layer 274.

In some embodiments, the third insulating layer 276 may be metal oxide or metal nitride and may include aluminum oxide, aluminum nitride, titanium oxide or titanium nitride.

In some embodiments, the fourth insulating layer 278 formed on the third insulating layer 276 may include silicon oxide in a similar way to the first insulating layer 272.

The insulating layer 27 may have a high barrier effect with respect to the active layer 23, because of a stacked structure including the first insulating layer 272, the second insulating layer 274, the third insulating layer 276 and the fourth insulating layer 278, when compared to a conventional insulating layer having a single layer of silicon oxide or silicon nitride. Thus, the insulating layer 27 may also be configured to protect the active layer 23 against oxygen or water. Also, as described below, a method of manufacturing the first insulating layer 272, the second insulating layer 274, the third insulating layer 276 and the fourth insulating layer 278 may be simple. Thus, the insulating layer 27 may be more easily used for a large area display.

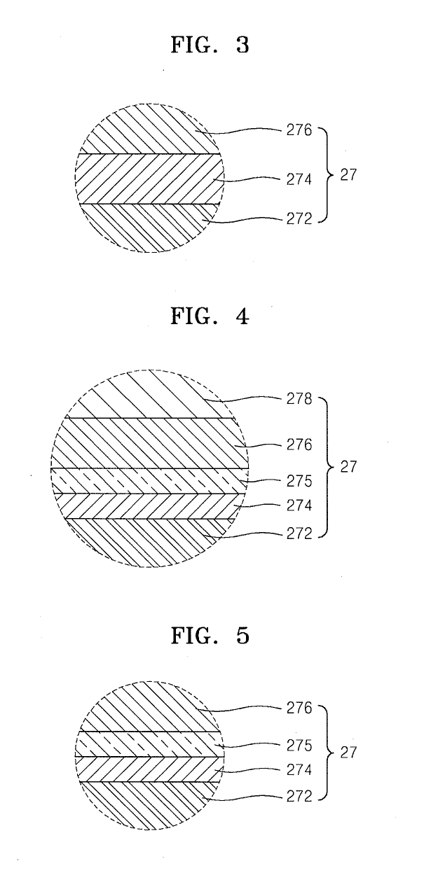

FIG. 3 is a cross-sectional view of the A part of FIG. 1, according to another embodiment of the present disclosure. FIG. 3 illustrates a structure in which the fourth insulating layer 278 is omitted, when compared to FIG. 2. When a barrier function is sufficient with the stacked structure including the first insulating layer 272, the second insulating layer 274, and the third insulating layer 276, the method step of forming of the fourth insulating layer 278 may be omitted.

FIG. 4 is a cross-sectional view of the A region of FIG. 1, according to another embodiment of the present disclosure. FIG. 4 illustrates a structure in which a metal layer 275 is further interposed between the second insulating layer 274 and the third insulating layer 276, when compared to FIG. 2. The metal layer 275 may include, for example, aluminum, titanium or the like. A barrier characteristic of the insulating layer 27 may be further improved because of the interposition of the metal layer 275. Although not shown in FIG. 4, it can be preferable that the metal layer 275 is not formed in a portion where the insulating layer 27 contacts the source electrode 25 and the drain electrode 26 of FIG. 1. As described below, this becomes possible by performing an oxidation treatment or a nitrifying treatment on ends of the metal layer 275.

FIG. 5 is a cross-sectional view of the A part of FIG. 1, according to another embodiment of the present disclosure. FIG. 5 illustrates a structure in which a metal layer 275 is further interposed between the second insulating layer 274 and the third insulating layer 276, when compared to FIG. 3. The descriptions of reference numerals in FIG. 5 are the same as those reference numerals in FIG. 4.

Next, a method of manufacturing the insulating layer 27 will be described in detail.

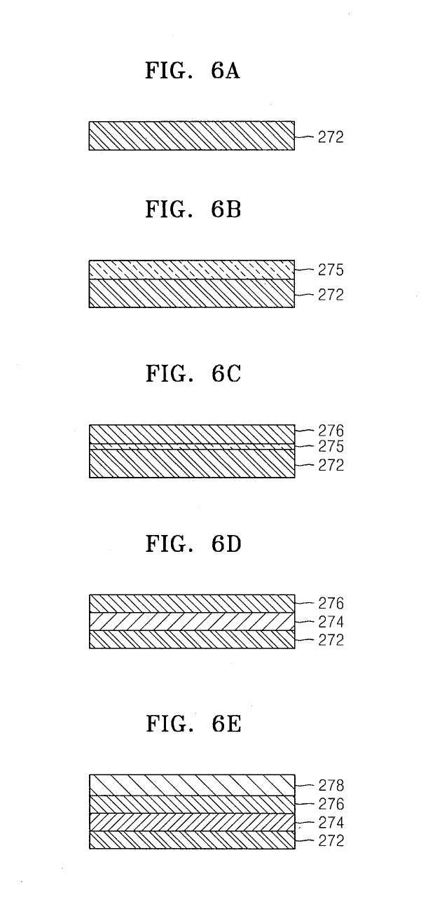

FIGS. 6A through 6E are cross-sectional views sequentially illustrating a method of manufacturing the insulating layer 27 of FIG. 2.

First, the first insulating layer 272 is formed to cover the TFT 2 of FIG. 1 (see FIG. 6A). The first insulating layer 272 may be formed by PECVD or sputtering. As described above, the first insulating layer 272 may be configured to protect the active layer 23 of the TFT 2 against pollution due to the formation of the metal layer 275 in a later process and be configured to facilitate diffusion of a metal by a thermal treatment in a later process.

Next, as illustrated in FIG. 6B, the metal layer 275 is formed on the first insulating layer 272. The metal layer 275 may be formed of aluminum or titanium, because an oxide layer or a nitride layer is solid. A thickness of the metal layer 275 may be about 50 Å, but embodiments of the present disclosure are not limited thereto.

Next, an upper part of the metal layer 275 is converted into the third insulating layer 276, as illustrated in FIG. 6C. Thus, metal oxide may be formed by performing a thermal treatment on the metal layer 275 under an oxygen atmosphere, or metal nitride may be formed by performing a N₂ plasma treatment on the metal layer 275. In more detail, the third insulating layer 276 may be formed of a layer having a good barrier characteristic, such as AlOₓ or TiN, and also formed to have a thickness of about 20 Å.

In this state, when an additional thermal treatment is performed at a temperature of about 250 Å to about 350 Å on the third insulating layer 276, illustrated in FIG. 6D, metals of the residual metal layer 275 are diffused into oxide of the first insulating layer 272. Thus, an upper portion of the first insulating layer 272 and the metal layer 275 that contact each other may be converted into the second insulating layer 274 and may be formed of metal oxide with a gradient of metal content. As a result, as illustrated in FIG. 6D, the first insulating layer 272, the second insulating layer 274 and the third insulating layer 276 may form a triple-layered structure and a metal layer formed with a pure metal may disappear.

Next, the fourth insulating layer 278 formed of silicon oxide may be selectively formed on the triple-layered structure by PECVD or sputtering in order to increase a thickness and productivity of the fourth insulating layer 278 (see FIG. 6E).

In the present disclosure, a layer formed of AlOₓ or Tin having an excellent barrier characteristic need not be manufactured by reactive sputtering or atomic layer deposition (ALD). Thus, the layer formed of AlOₓ or Tin may be easily used on a large-sized substrate, which means the structure may be more easily mass produced.

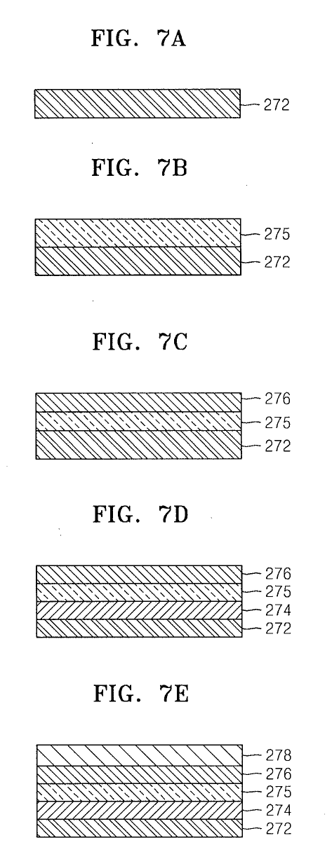

FIGS. 7A through 7E are cross-sectional views sequentially illustrating a method of manufacturing the insulating layer 27 of FIG. 4, according to another embodiment of the present disclosure. In FIGS. 7A through 7E, the processes illustrated in FIGS. 7A through 7C are the same as those of FIGS. 6A through 6C. Next, when the second insulating layer 274 is formed by performing a thermal treatment on the metal layer 275, the entire residual metal layer 275 is not diffused into the first insulating layer 272. Instead, a part of the metal layer 275 remains, so that the metal layer 275 is interposed between the second insulating layer 274 and the third insulating layer 276 (see FIG. 7D). Accordingly, the first insulating layer 272, the second insulating layer 274, the third insulating layer 276, and the fourth insulating layer 278 may form a quadruple-layered structure. Next, the fourth insulating layer 278 formed of silicon oxide may be selectively formed on the quadruple-layered structure by PECVD or sputtering in order to increase a thickness and productivity of the fourth insulating layer 278 (see FIG. 7E).

It will be appreciated by those skilled in the art that various modifications and changes may be made without departing from the scope of the present disclosure. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Further, while the present disclosure has described certain exemplary embodiments, it is to be understood that the scope of the disclosure is not limited to the disclosed embodiments, but, on the contrary, is intended to cover various modifications and equivalent arrangements included within the spirit and scope of the appended claims and equivalents thereof.

What is claimed is:

1. An organic light-emitting display device, comprising:
a thin-film transistor (TFT) comprising a gate electrode, an active layer insulated from the gate electrode, and source and drain electrodes insulated from the gate electrode and contacting the active layer;
an organic light-emitting diode electrically connected to the TFT; and
an insulating layer interposed between the TFT and the organic light-emitting diode,
wherein the insulating layer comprises a first insulating layer covering the TFT, a second insulating layer formed of a metal oxide and formed on the first insulating layer, and a third insulating layer formed of a metal oxide or a metal nitride and formed on the second insulating layer.

2. The device of claim 1, wherein the second insulating layer has a gradient of metal content with respect to its thickness.

3. The device of claim 2, wherein the metal content decreases toward the first insulating layer.

4. The device of claim 3, wherein the metal is formed of aluminum, titanium or an alloy thereof.

5. The device of claim 1, wherein the insulating layer further comprises a fourth insulating layer formed on the third insulating layer.

6. The device of claim 1, wherein the third insulating layer is formed of aluminum oxide, aluminum nitride, titanium oxide or titanium nitride.

7. The device of claim 1, wherein the insulating layer further comprises a metal layer between the second insulating layer and the third insulating layer.

8. The device of claim 7, wherein the metal layer is formed of aluminum, titanium or an alloy thereof.

9. The device of claim 1, wherein the active layer is formed of an oxide semiconductor.

10. The device of claim 1, wherein the first insulating layer is formed of silicon oxide.

11. A method of manufacturing an organic light-emitting display device, the method comprising:
forming a thin-film transistor (TFT) on a substrate, wherein the TFT comprises a gate electrode, an active layer insulated from the gate electrode, and source and drain electrodes insulated from the gate electrode and contacting the active layer;
forming an insulating layer covering the TFT; and
forming an organic light-emitting diode on the insulating layer, wherein the organic light-emitting diode is electrically connected to any one of the source electrode and the drain electrode,
wherein the forming of the insulating layer comprises forming a first insulating layer covering the TFT; forming a metal layer on the first insulating layer; forming a part of the metal layer as a third insulating layer by oxidizing or nitrifying a surface of the metal layer opposite to the first insulating layer; and forming a second insulating layer formed of metal oxide in a portion where the first insulating layer and the metal layer contact each other.

12. The method of claim 11, wherein the forming of the second insulating layer comprises performing a thermal treatment on the metal layer.

13. The method of claim 11, wherein the second insulating layer has a gradient of metal content with respect to its thickness.

14. The method of claim 13, wherein the metal content decreases toward the first insulating layer.

15. The method of claim 14, wherein the metal is formed of aluminum, titanium or an alloy thereof.

16. The method of claim 11 further comprising forming a fourth insulating layer on the third insulating layer.

17. The method of claim 14, wherein the third insulating layer is formed of aluminum oxide, aluminum nitride, titanium oxide or titanium nitride.

18. The method of claim 11 further comprising forming a metal layer between the second insulating layer and the third insulating layer.

19. The method of claim 18, wherein the metal layer is formed of aluminum, titanium or an alloy thereof.

20. The method of claim 11, wherein the active layer is formed of an oxide semiconductor.

21. The method of claim 11, wherein the first insulating layer is formed of silicon oxide.
